(19) United States
(12) Patent Application Publication
(10) Pub. No.: US 2018/0372781 A1
(43) Pub. Date: Dec. 27, 2018

(54) SYSTEMS AND METHODS FOR LOW-POWER CURRENT & VOLTAGE SENSING USING AN OPTICALLY COUPLED ISOLATOR

(71) Applicant: International Technological University Foundation, Inc., San Jose, CA (US)

(72) Inventor: Karl Lin WANG, Los Altos, CA (US)

(73) Assignee: International Technological University Foundation, Inc., San Jose, CA (US)

(21) Appl. No.: 15/719,312

(22) Filed: Sep. 28, 2017

Related U.S. Application Data
(60) Provisional application No. 62/524,609, filed on Jun. 25, 2017.

(51) Int. Cl. G01R 15/22; G01R 19/155; G01R 1/20

(52) U.S. Cl. CPC G01R 15/22; G01R 1/20; G01R 19/155

(57) ABSTRACT

Described herein are systems and methods for low-power voltage sensor circuits and current sensor circuits using an optically coupled isolator. In various embodiments, opto-couplers replace bulky transformers that are used in common designs. In embodiments, an optically coupled isolator is used as a power gate to reduce power consumption. Further power savings may be obtained by selecting appropriate phototransistors and adjustable bias resistors to set the forward current of a photodiode as small as functionally possible to reduce battery discharge while providing sufficient gain for the optical transistor. In certain embodiments, the bias voltage point may be chosen to be at the turn-on voltage of the photodiode. In embodiments, power consumption of the voltage and current sensors may be adjusted by adjusting the frequency of a power-gating control signal, which may be controlled by a microcontroller. Embodiments may be used to produce low-cost alternatives that provide small form factor, high measurement accuracy, reliability, and longevity.

### CROSS-REFERENCE To RELATED APPLICATION

This application claims the priority benefit under 35 USC § 119(e) to U.S. Prov. Pat. App. No. 62/524,609 (Docket No. 20136-2150P), filed on Jun. 25, 2017, entitled “Systems and Methods for Low-Power Current & Voltage Sensing Using an Optically Coupled Isolator,” and listing Karl Wang as inventor. The aforementioned patent document is incorporated by reference herein in its entirety and for all purposes.

### BACKGROUND

### A. Technical Field

The present invention is related generally to sensors and more particularly to systems and methods for low-power current and voltage sensing using an optically coupled isolator.

### B. Background

Smart meter voltage and current sensing systems require electrical circuit isolation between high voltage and the low voltage domains. One common way to achieve electrical isolation is to use transformers. One disadvantage of using a transformer to monitor voltage or current is that voltage and current sensing circuits are easily tampered with, e.g., by placing a strong magnet in close proximity the metering device to saturate the transformer core. Another drawback of designs that use transformers is that such designs tend to be prone to electromagnetic interference that negatively affects measurement accuracy. Given the ubiquity of metering devices, it would be desirable to have designs that have low power consumption, such that the devices can operate for extended periods of time, thereby, reducing production and maintenance costs. Further, it would be desirable to have low-maintenance smart meters that provide enhanced system performance, reliability, manufacturability, testability, and operational capacity. Accordingly, what is needed are systems and methods that address such needs.

### BRIEF DESCRIPTION OF THE DRAWINGS

References will be made to embodiments of the invention, examples of which may be illustrated in the accompanying figures. These figures are intended to be illustrative, not limiting. Although the invention is generally described in the context of these embodiments, it should be understood that it is not intended to limit the scope of the invention to these particular embodiments. Items in the figures are not to scale.

FIG. 1 is an illustration of a smart meter system in accordance with embodiments of the present patent document.

FIG. 2 is an illustration of a smart meter in accordance with embodiments of the present patent document.

FIG. 3 is an illustration of a circuit design for current sensing transistor in an emitter follower configuration with load resistor connected to the emitter in accordance with embodiments of the present patent document.

FIG. 4 is an illustration of a circuit for current sensing for the open collector configuration with a load resistor connected to the collector in accordance with embodiments of the present patent document.

FIG. 5 is an illustration of a circuit for voltage sensing transistor in an emitter follower configuration with a load resistor connected to the emitter in accordance with embodiments of the present patent document.

FIG. 6 is an illustration of a circuit for voltage sensing transistor in an open collector configuration with a load resistor connected to the collector in accordance with embodiments of the present patent document.

FIG. 7 is an illustration of a circuit for voltage and current sensing for the emitter follower configuration for a 3-phase power line application in accordance with embodiments of the present patent document.

FIG. 8 is an illustration of a power-gated circuit for current sensing in accordance with embodiments of the present patent document.

FIG. 9 graphically depicts output voltage values of the circuit depicted in FIG. 8 in accordance with embodiments of the present patent document.

FIG. 10 is a chart that depicts a lifetime estimation vs. sample frequency in accordance with embodiments of the present patent document.

FIG. 11 illustrates another power-gated sensing circuit for voltage sensing in accordance with embodiments of the present patent document.

### DETAILED DESCRIPTION OF EMBODIMENTS

In the following description, for purposes of explanation, specific details are set forth in order to provide an understanding of the invention. It will be apparent, however, to one skilled in the art that the invention can be practiced without these details. Furthermore, one skilled in the art will recognize that embodiments of the present invention, described below, may be implemented in a variety of ways, such as a process, an apparatus, a system, a device, or a method on a tangible computer-readable medium.

Components, or modules, shown in diagrams are illustrative of exemplary embodiments of the invention and are meant to avoid obscuring the invention. It shall also be understood that throughout this discussion that components may be described as separate functional units, which may comprise sub-units, but those skilled in the art will recognize that various components, or portions thereof, may be divided into separate components or may be integrated together, including integrated within a single system or component. It should be noted that functions or operations discussed herein may be implemented as components. Components may be implemented in software, hardware, or a combination thereof.

Furthermore, connections between components or systems within the figures are not intended to be limited to direct connections. Rather, data between these components may be modified, re-formatted, or otherwise changed by intermediary components. Also, additional or fewer connections may be used. It shall also be noted that the terms “coupled,” “connected,” or “communicatively coupled” shall be understood to include direct connections, indirect connections through one or more intermediary devices, and wireless connections.

Reference in the specification to “one embodiment,” “preferred embodiment,” “an embodiment,” or “embodiments” means that a particular feature, structure, characteristic, or function described in connection with the embodiment is included in at least one embodiment of the invention and may be in more than one embodiment. Also, the appearances of the above-noted phrases in various places in the specification are not necessarily all referring to the same embodiment or embodiments.

The use of certain terms in various places in the specification is for illustration and should not be construed as limiting. A service, function, or resource is not limited to a single service, function, or resource; usage of these terms may refer to a grouping of related services, functions, or resources, which may be distributed or aggregated.

The terms “include,” “including,” “comprise,” and “comprising” shall be understood to be open terms and any lists the follow are examples and not meant to be limited to the listed items. Any headings used herein are for organizational purposes only and shall not be used to limit the scope of the description or the claims. Each reference mentioned in this patent document is incorporate by reference herein in its entirety.

Furthermore, one skilled in the art shall recognize that: (1) certain steps may optionally be performed; (2) steps may not be limited to the specific order set forth herein; (3) certain steps may be performed in different orders; and (4) certain steps may be done concurrently.

The present invention is related generally to measuring power and to smart meter systems. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

### A. Voltage and Current Sensing Circuit Embodiments

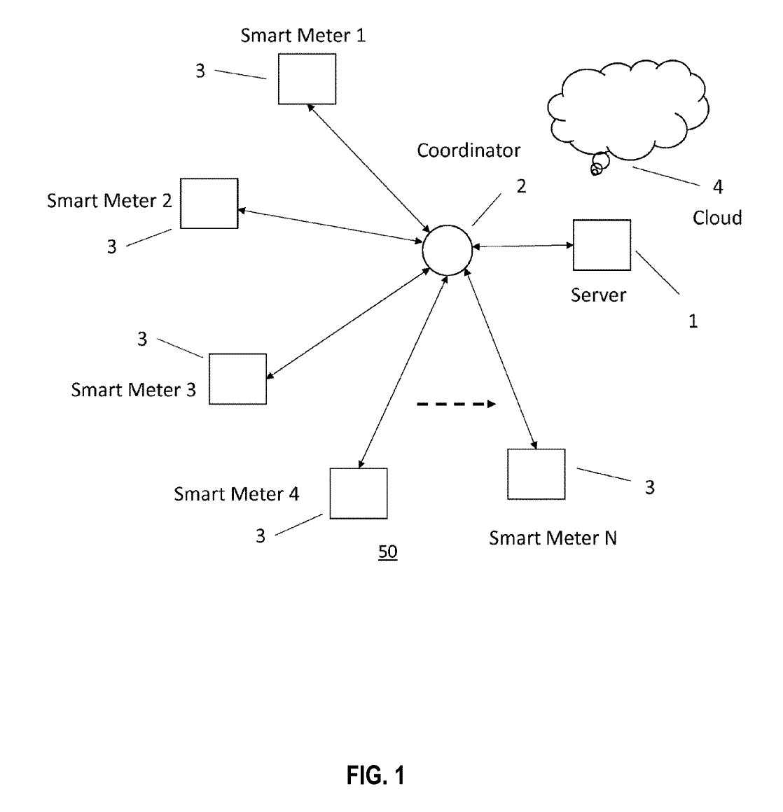

FIG. 1 is an illustration of the smart meter system 50 in accordance with an embodiment. The smart meter system 50 comprises a local server 1 connected to a coordinator 2 and smart meters 3 (smart meter 1-N). In one embodiment, the local server 1 is connected to the coordinator 2 via wires. In another embodiment, the local server 1 is connected to the coordinator 2 wirelessly.

The smart meter system 50 is a many-to-one data communication topology. In this embodiment, the local server 1 issues a command to the coordinator 2 which executes the command by sending a corresponding data packet wirelessly to the smart meters 3 by a radio frequency (RF) link, e.g. ZigBee that may or may not support an industry standard such as IEEE 802.14.5. Then the smart meters 3 send an appropriate response back to the coordinator 2 by the same RF link. Power usage data sent by the smart meters 3 can be stored in a database hosted in the local server 1 or an internet cloud 4.

The power usage can be accessed for example by displaying web pages using any device that is connected to the local server or the internet. The database can be analyzed to determine optimal power usage and distribution. The power usage can also be analyzed to enable system control, e.g. cut off the power if necessary.

The local server 1 issues commands to the coordinator 2 through a coordinator-server interface control register. The coordinator server interface control register typically resides within the coordinator 2 and allows for the communication between the local sever 1 and the coordinator 2. The coordinator server interface control register streamlines and enhances the performance of tasks between server 1 and coordinator 2.

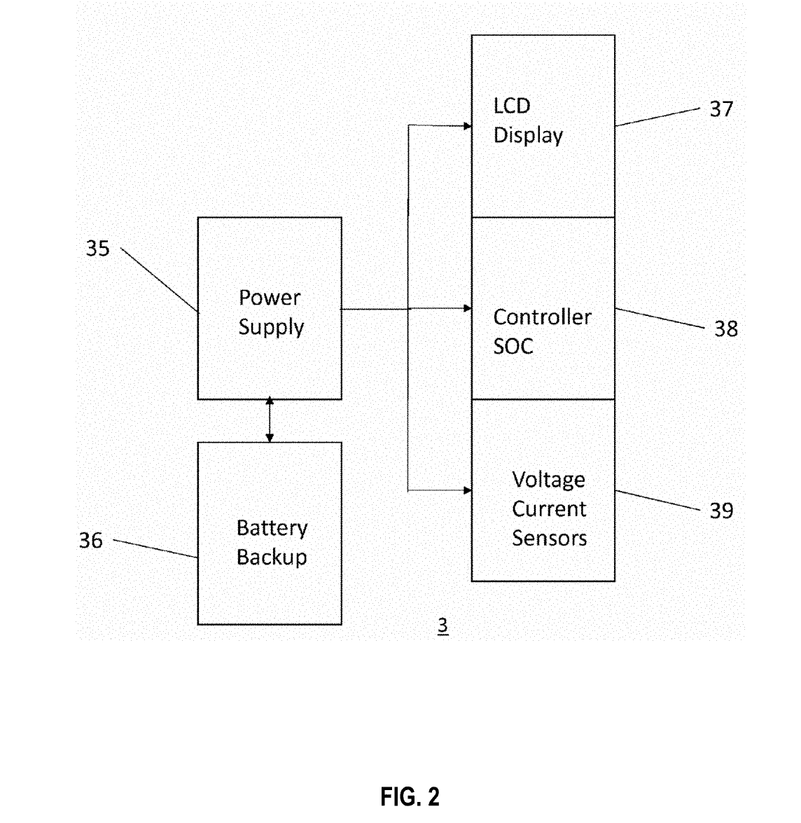

FIG. 2 is an illustration of a smart meter 3 in accordance with an embodiment. The smart meter 3 comprises a power supply 35, a battery backup 36, a liquid crystal display or LCD display 37, a RF controller System-on-Chip (SOC) 38, and voltage and current sensors 39. The battery backup 36 provides a non-interruptible power supply in the event of a power failure. The battery backup 36 enables the detection of power failure in the smart meter 3. The status of the battery backup 36 is reported in the STATUS register.

A key feature of the present invention is that there is no need for a transformer when sensing voltage and current. This transformer-less approach is made possible by optically isolating a high voltage portion of the smart meter from a low voltage portion. In so doing, resistors can be utilized to provide the current or voltage sensing properties of the smart meter. By eliminating the transformer, the smart meter can be designed physically smaller, less costly (as the cost of resistors and isolators is typically much less than that of a transformer), and tamper-proof against its core being saturated, e.g., to corrupt the meter's readings. To describe the features of the present invention in more detail refer now to the following description in conjunction with the accompanying Figures.

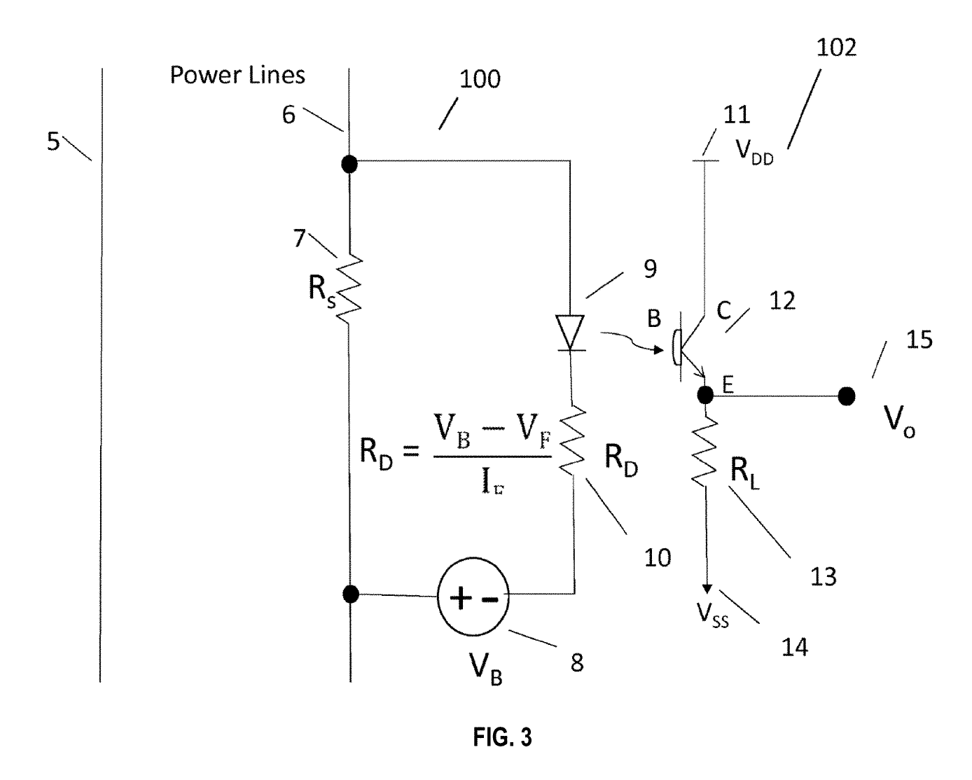

FIG. 3 is an illustration of a circuit design for a current sensing portion of voltage and current sensors 39 in the smart meter 3 of FIG. 2 for a single-phase power line system. The first terminal of a small shunt resistor Rₛ 7 is connected in series with the hot line of power line pair 6 which is a high voltage portion 100; the other power line 5 is the neutral or ground line. The cathode terminal of an infra-red light-emitting diode (IR LED) 9 is connected to the first terminal of resistor Rₛ. The anode terminal of IR LED is connected with the first terminal of resistor R_{D} 10. The second terminal of R_{D} 10 is connected to the negative terminal of a voltage source V_{B} 8. The positive terminal of V_{B} is connected to the second terminal of Rₛ 7.

An optical transistor 12 has a base terminal B that is optically coupled to the IR LED which is a low voltage portion 102. The collector terminal C is connected to the V_{DD} terminal 11. The emitter terminal E is connected to the first terminal of a resistor R_{L} 13 in an emitter follower configuration. The second terminal of R_{L} 13 is connected to the V_{SS} terminal 14. An output signal V_{O} 15 is connected to the emitter terminal E of the optical transistor 12. The optically coupled isolator comprises of the IR LED 9 and the optical transistor 12.

The IR LED 9 is biased in the forward conduction region using a voltage source V_{B} 8. This bias condition is determined by choosing a current-limiting resistor R_{D} 10 that is equal to the difference of bias voltage source V_{B} 8 and the forward voltage V_{F} of the IR LED diode divided by the forward current I_{F} of the IR LED diode. This bias condition enables the IR LED diode to operate at a voltage bias condition to maximize the sensitivity of the optically coupled isolator and minimize the current consumption.

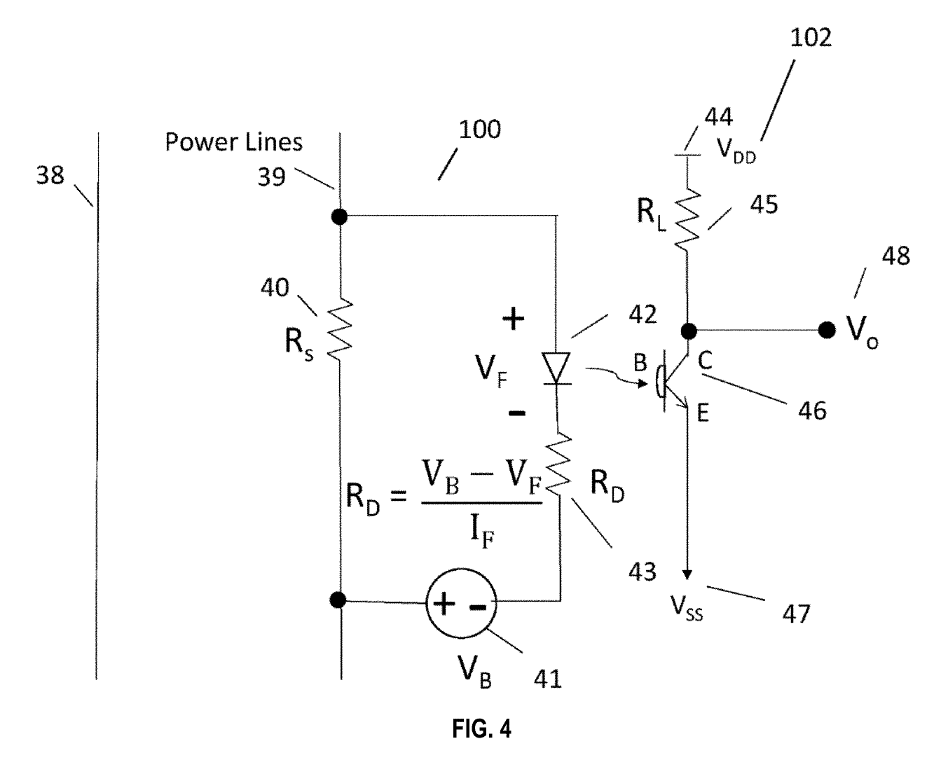

FIG. 4 is an illustration of the output transistor in the open collector configuration with a load resistor R_{L} 45. The first terminal of R_{L} 45 is connected to V_{DD} and the second terminal of R_{L} 45 is connected to the collector terminal C of the optical transistor 46. The output voltage V_{O} 48 is taken from the collector terminal C of the optical transistor 46.

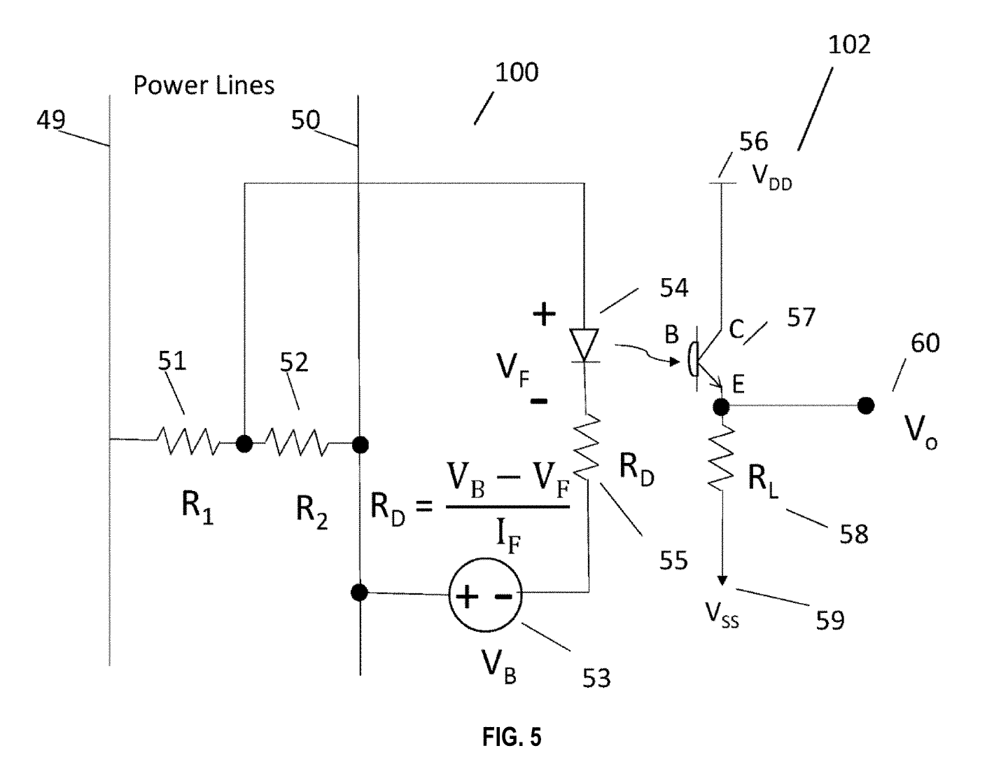

FIG. 5 is an illustration of a circuit for voltage sensing transistor in the emitter follower configuration with a load resistor R_{L} 58. The voltage sensing circuit comprises of a voltage divider comprising resistor R₁ 51 and R₂ 52 that are connected in series across the hot power lines 49 and the neutral power line 50 where the first terminal of R₁ 51 is connected to the hot power lines 49, the second terminal of R₁ 51 is connected to the first terminal of R₂ 52, and the second terminal of R₂ 52 is connected to the neutral power line 50 which is a high voltage portion 100. The first terminal of resistor R₂ 52 is connected to the cathode terminal of the IR LED 54. The anode terminal of IR LED 54 is connected to the first terminal of resistor R_{D} 55. The second terminal of R_{D} 55 is connected to the negative terminal of a voltage source V_{B} 53. The positive terminal of V_{B} 53 is connected to the second terminal of R₂ 52.

An optical transistor 57 has a base terminal B that is optically coupled to the IR LED which is a low voltage portion 102. The collector terminal C is connected to the VDD terminal 56. The emitter terminal E is connected to the first terminal of a resistor R_{L} 58 in the emitter follower configuration. The second terminal of R_{L} 58 is connected to the V_{SS} terminal 59. The output voltage V_{O} is taken from the emitter terminal E of the optical transistor 57.

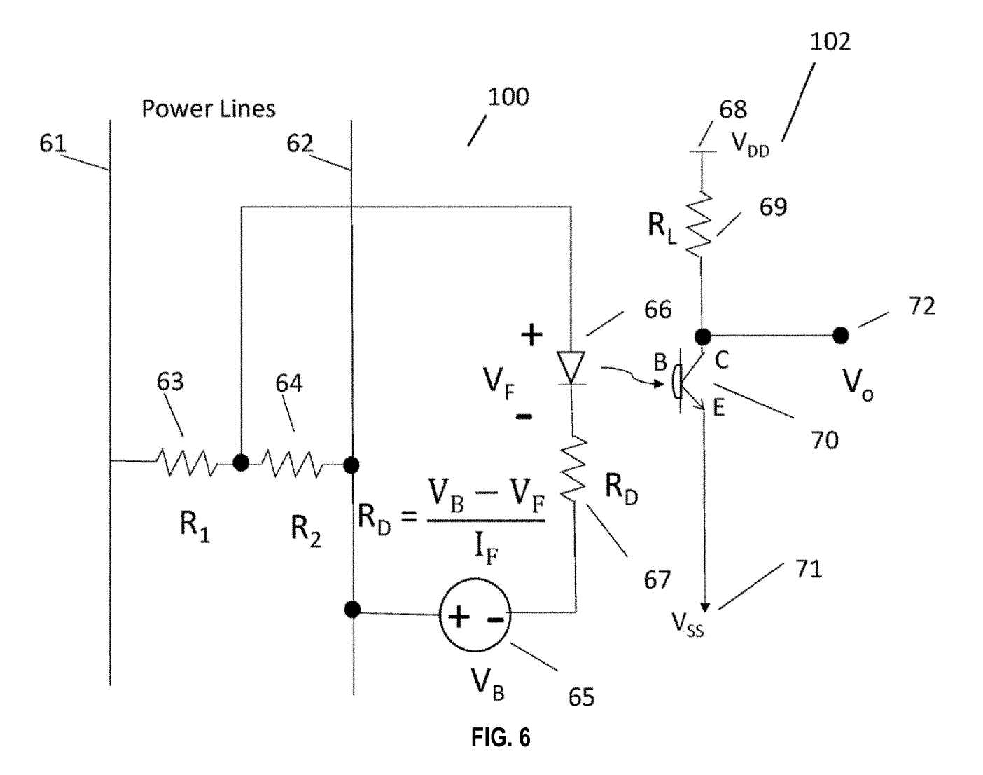

FIG. 6 is an illustration of a circuit for a voltage sensing transistor in the open collector configuration with a load resistor R_{L} 69. An optical transistor 70 has a base terminal B that is optically coupled to the IR LED 66. The emitter terminal E is connected to the V_{SS} terminal 71. The collector terminal C is connected to the second terminal of a resistor R_{L} 69 in the open collector configuration. The first terminal of R_{L} 69 is connected to the VDD terminal 68. The output voltage V_{O} 72 is taken from the collector terminal C of the optical transistor 70.

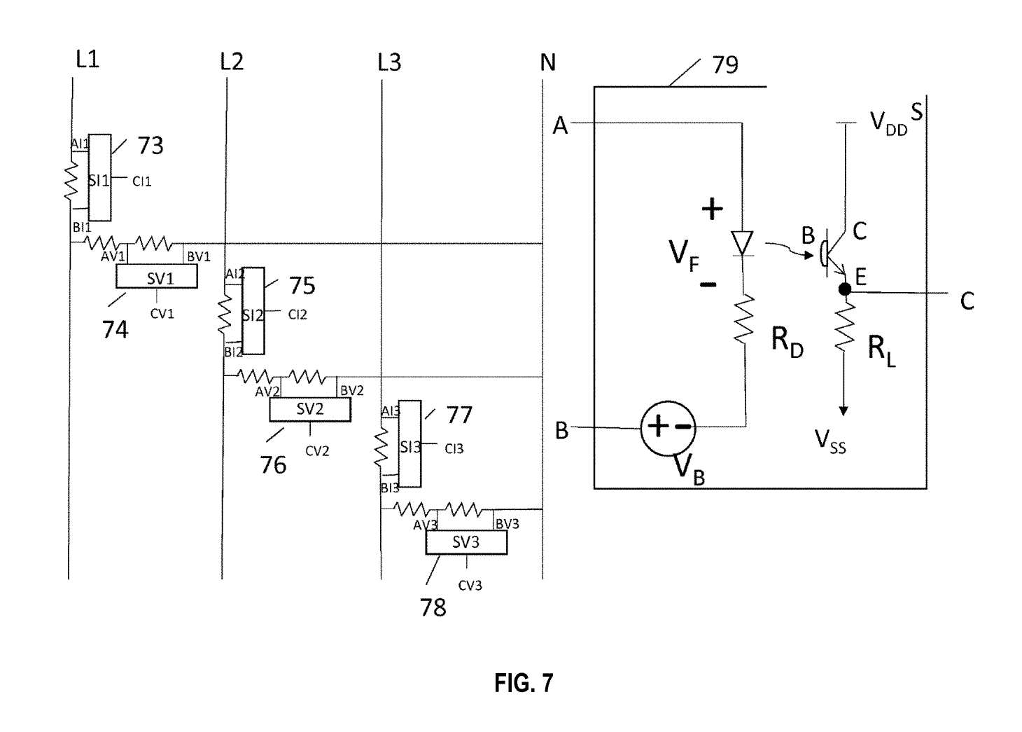

FIG. 7 is an illustration of a circuit for voltage and current sensing for the emitter follower configuration for a 3-phase power line application. The circuit SI1 73 senses the current of L1 phase; the circuit SV1 74, senses the voltage of L1 phase; the circuit SI2 75, senses the current of L2 phase; the circuit SV2 76, senses the voltage of L2 phase; the circuit SI3 77, senses the current of L3 phase; the circuit SV3 78, senses the voltage of L3 phase.

A smart meter system voltage and current sensing are performed as voltage drops across a shunt resistor in series with the power line or from a voltage divider connected across the power lines. These voltages are optically coupled and electrically isolated to the inputs of the low voltage circuits by using optically coupled isolators. Circuits for the voltage and current sensing method are described using resistors and optically coupled isolators. The advantages of this transformer-less method as compared to the transformer approach are direct sensing of current and voltage that enables AC power and energy measurements for non-resistive loads, tamper proof for secure power measurements, compact sizes, and low costs.

Embodiments of such systems are described in U.S. Pat. No. 9,000,753, which issued on Apr. 7, 2015, and lists Karl L. Wang as inventor and in U.S. Pat. No. 9,377,490, which issued on Jun. 28, 2016, and lists Karl L. Wang as inventor; each of the foregoing patent documents is incorporated by reference herein in its entirety.

### B. Power-Gated Voltage and Current Sensing Circuit Embodiments

Embodiments of the sensor designs presented above use an optical coupled isolator to achieve electrical isolation and may use a small, e.g., coin-sized, battery to reduce the overall sensor circuit board size. Because these designs may be implemented with low capacity batteries, it may be preferable to have low-power techniques to help extend the life of the battery, thereby reducing costs and increasing longevity. Accordingly, embodiments presented above may be altered to include one or more low-power design embodiments to improve battery life. In embodiments, power-gating techniques may also include adjusting measurement frequency to significantly reduce battery power consumption.

### 1. Embodiments of Power-Gated Sensor Design

The embodiments presented above show that the sensed current or voltages in the high voltage power lines are optically coupled and electrically isolated from the low voltage circuits. One of the challenges is power-gating the circuit given the low voltage and high voltage isolated circuits. To address this problem, in embodiments, an optical transistor may be incorporated into the design to serve as a power-gating switch that can be used to turn on the sensing circuit, as needed, when voltage or current sensing is performed in order to reduce power consumption.

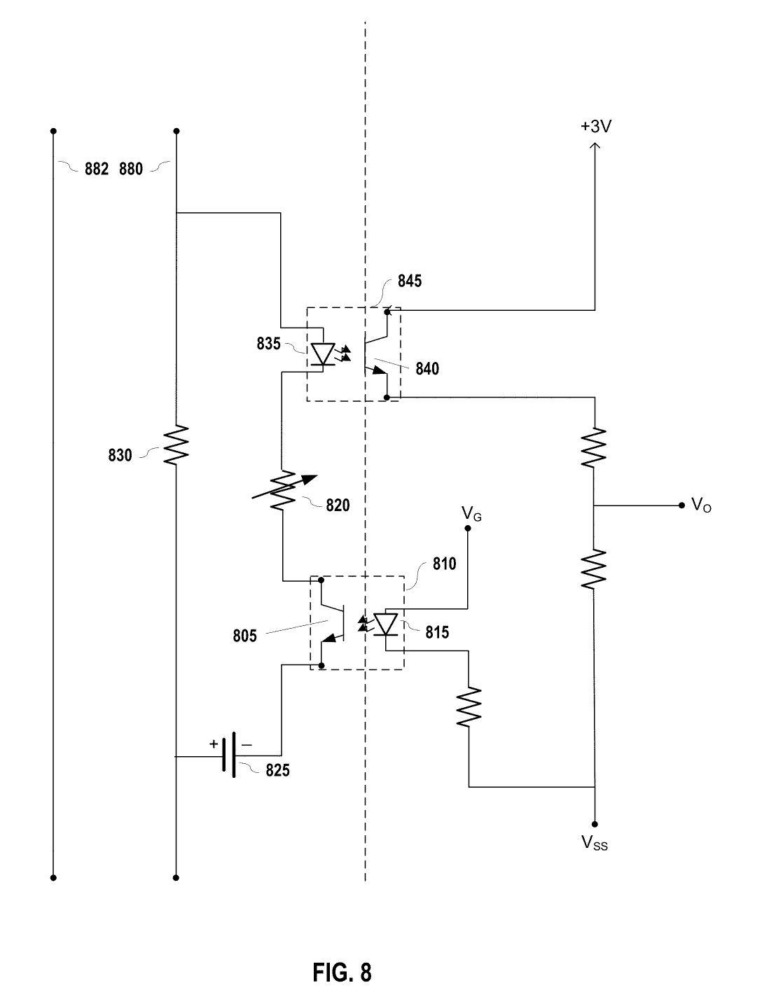

FIG. 8 is an illustration of a power-gated circuit for current sensing in accordance with embodiments of the present patent document. In embodiments, the circuit shown in FIG. 8 comprises optical isolator 810, 845, bias resistor 820, battery 825, sampling resistor 830, gate voltage V_{G}. In embodiments, optical isolator 810 comprises optical transistor 805 and IR LED 815. Similarly, optical isolator 845 may comprise optical transistor 840 and IR LED 835. In embodiments, optical transistor 805 may be implemented as a photodiode, a photo-triac, or any other optical receiver known in the art.

In embodiments, optical transistor (e.g., phototransistor) 805 is an optical receiver that may be optically coupled to a light-emitting source 815, such as an IR LED, such that the optical isolator forms a power-gating switch 810 that couples the high voltage circuit and the low voltage circuit. In embodiments, the optical transistor 805 may be controlled by a power-gating signal, V_{G}, that may be generated, for example, by a microcontroller unit (not shown) that is used to turn on and off the sensing circuit. By turning on the sensing circuit only when voltage or current sensing is performed, the power consumption of a metering device that employs the sensing circuit can be significantly decreased. In embodiments, a battery 825 (e.g., a coin battery) and a bias resistor 820 may be used, e.g., to bias the optical diode in the forward conduction region.

In embodiments, a sampling resistor 830 (e.g., series resistor) connected in series with the high voltage power line 880 may be used to enable current sensing. In embodiments, to perform voltage sensing, a resistive voltage divider (not depicted in FIG. 8) that is connected across the power lines 880, 882 may be used. Examples of voltages divider configurations that may be employed are depicted in FIGS. 5 and 6. It is understood that additional design features may be implemented to further reduce the power consumption.

In embodiments, a phototransistor (e.g., phototransistor 805) and adjustable bias resistor (e.g., current-limiting resistor 820) may be selected to set the forward current of the photodiode as small as possible, to reduce battery discharge while providing sufficient gain for the optical transistor. In embodiments, the bias voltage point is chosen to be at the turn-on voltage of the LED 835.

In embodiments, the power-gated circuit in FIG. 8 is hermetically sealed and, thus, free from ambient light that, otherwise, may potentially affect the accuracy if a current and voltage sensing. In addition, due to its opto-coupling features, power-gated circuit is also practically immune to magnetic and electromagnetic interference.

### 2. Prototyping & Testing

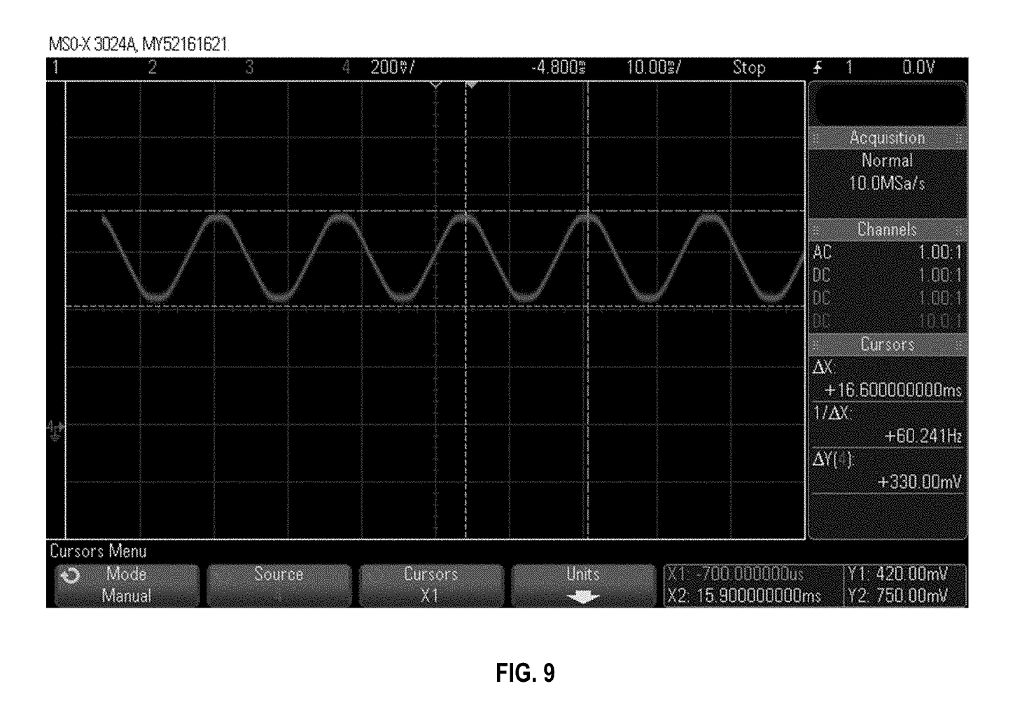

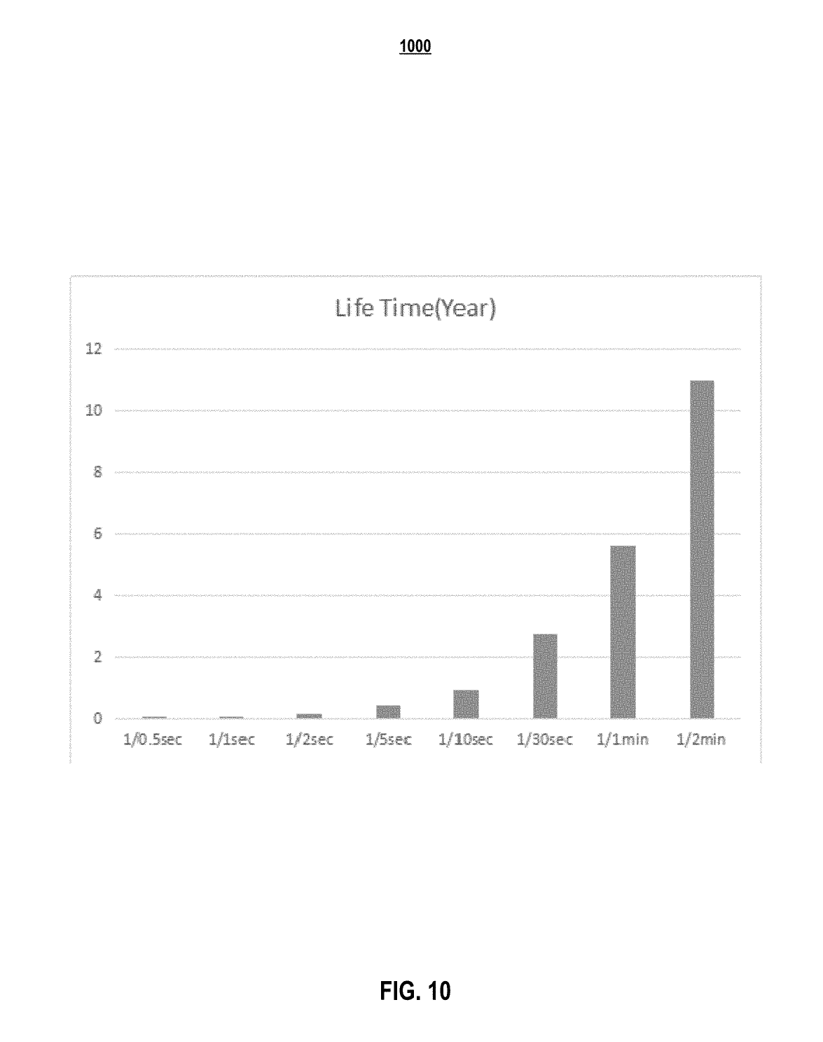

It shall be noted that these experiments and results discussed with reference to FIG. 9 FIG. 10, below, are provided by way of illustration. Experiments were performed under specific conditions using a specific embodiment or embodiments; accordingly, neither these experiments nor their results shall be used to limit the scope of the disclosure of the current patent document.

Certain embodiments were used to build prototype sensing circuits on an approximately 1″×1″ breadboard that is similar to the size of a common CR2032 coin battery. It should be noted the further form size reductions may be achieved. In embodiments, an automatic calibration process was used to calibrate sensors by using known calibration current and voltage sources to achieve measurement accuracies that may exceed 99%.

In embodiments, sensing circuits are capable of operating and sampling current and/or voltage for 135 hours using a 220 mAh coin battery. By reducing the sampling frequency and/or sampling time length (e.g., 10 sampling cycles), the expected battery life can be extended. Given an exemplary sampling rate of one sample taken every 2 minutes, the battery lifetime may exceed 10 years.

FIG. 9 illustrates the amplitude of an AC signal that represents an output voltage value, V_{O}. In embodiments, V_{O} is proportional to an AC current measured on a high voltage power line. For example, V_{O} may be proportional to the AC current that is measured on high voltage power line 880 by sampling resistor 830 shown in FIG. 8.

In detail, the AC current causes a voltage drop across resistor 830 that is proportional to the AC current and controls the current in LED 835. Assuming that, in embodiments, the amount of current flowing through LED 835 is proportional to the resulting light produced by LED 835, and given that the amount of light emitted by LED 835 is received by optical transistor 840 and determines the current flowing through optical transistor 840 that, in turn, is an indicator of the output voltage, V_{O}, of the circuit, the AC current flowing in resistor 830 will be proportional to the output voltage V_{O} generated by the low-power portion of the sensing circuit.

FIG. 10 is a chart that depicts a lifetime estimation vs. sample frequency in accordance with embodiments of the present patent document. As shown in FIG. 10, as the sample frequency decreases, the lifetime of the battery in the sensing circuit increases. In embodiments, with a power-gating and sampling frequency of 0.5 per minute, controlled by a microcontroller unit, the power consumption can be dramatically reduced. Thus, it can be seen that using a coin-size battery, the battery lifetime of approximately 10 years can be achieved.

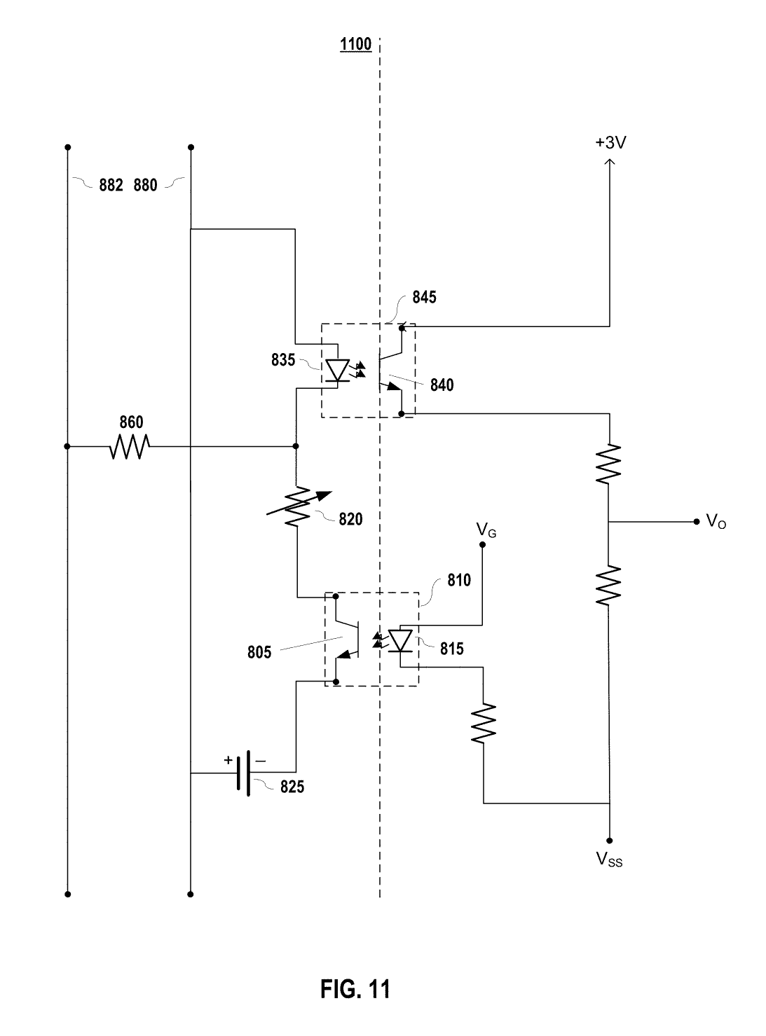

FIG. 11 illustrates another power-gated sensing circuit in accordance with embodiments of the present patent document. The implementation as depicted in FIG. 11 combines the functions of the voltage divider (denoted as R1, R2 in FIG. 5 or 6) and a bias resistor (denoted as numeral 55 in FIG. 5 or numeral 67 in FIG. 6) into resistor 860 and bias resistor 820. This combination advantageously eliminates the need for a separate voltage divider resistor (denoted as R2 FIG. 5 and FIG. 6).

In embodiments, resistor 860 samples a voltage that is representative of the voltage between two power lines. In embodiments, the voltage drop across resistor 860 draws a current that may alter the bias voltage across bias resistor 820 and, consequently, the amount of current flowing in IR LED 835. As discussed with reference to FIG. 8, the amount of light emitted by IR LED 835 determines the current flowing through optical transistor 840 and acts as an indicator of the output voltage V_{O}. As a result, in embodiments, the AC voltage drop across resistor 820 may be directly proportional to the output voltage V_{O} that is generated by the low-power portion of the sensing circuit in FIG. 11.

It will be appreciated to those skilled in the art that the preceding examples and embodiments are exemplary and not limiting to the scope of the present disclosure. It is intended that all permutations, enhancements, equivalents, combinations, and improvements thereto that are apparent to those skilled in the art upon a reading of the specification and a study of the drawings are included within the true spirit and scope of the present disclosure. It shall also be noted that elements of any claims may be arranged differently including having multiple dependencies, configurations, and combinations.

What is claimed is:

1. A method for sensing voltage or current in a high voltage circuit using low power, the method comprising:
coupling a sensor to a low voltage circuit and a high voltage circuit that are electrically isolated from each other;
coupling a switch to the low voltage circuit and the high voltage circuit;
using the low voltage circuit to activate the switch, the switch causing the sensor to be energized;
in response to the sensor being energized, detecting a current that is representative of at least one of a high voltage and a high current present in the high voltage circuit; and
using the low voltage circuit to generate an output voltage representative of at least one of the high voltage and the high current.

2. The method according to claim 1, further comprising sampling the current via a sampling resistor that carries the current.

3. The method according to claim 1, further comprising using a voltage divider coupled between two power lines comprised in the high voltage circuit to sample the high voltage.

4. The method according to claim 1, further comprising adjusting, via a bias resistor, a forward current of a light source to operate the light source at a turn-on voltage of the light source.

5. The method according to claim 4, wherein a bias voltage of the bias resistor is adjusted by a battery in the high voltage circuit.

6. The method according to claim 1, further comprising deactivating the sensing circuit according to a gating voltage that is applied to the switch to reduce a power consumption of the sensor.

7. The method according to claim 1, wherein the output voltage varies proportionally to the current.

8. A system for sensing voltage or current in a high voltage circuit using low power, the system comprising:
a sensor configured to optically couple a low voltage circuit to a high voltage circuit, the sensor capable of detecting a current that is representative of at least one of a high voltage and a high current in the high voltage circuit;
a switch configured to optically couple the low voltage circuit to the high voltage circuit, the switch, in response to being activated, causes the sensor to be energized; and
an output node coupled to the low voltage circuit to generate an output voltage representative of the current.

9. The system according to claim 8, wherein the sensor comprises a first light source and a first optical receiver that is electrically isolated from the first light source, and wherein the switch comprises a second light source and a second optical receiver that is electrically isolated from the second light source.

10. The system according to claim 9, wherein the second optical receiver is one of a phototransistor, a photodiode, and a photo-triac.

11. The system according to claim 9, wherein at least one of the first and second light sources is an infra-red light-emitting diode.

12. The system according to claim 9, further comprising a battery that is coupled to the first light source and the second optical receiver.

13. The system according to claim 9, further comprising a sampling resistor coupled to the second optical receiver, the sampling resistor conducts the current.

14. The system according to claim 9, further comprising a bias resistor coupled between the sensor and the switch to adjust a bias condition of the first light source, the sensor being unaffected by electromagnetic interference and being in a hermetically sealed environment that excludes ambient light.

15. The system according to claim 9, wherein the low voltage circuit comprises a gating voltage node that is coupled to the switch, the gating voltage activates the switch that causes the sensor to be energized.

16. The system according to claim 15, wherein the gating signal is generated by a microcontroller that adjusts a sensing period and a sampling period such that a power consumption of the sensor is reduced.

17. A system for sensing voltage or current in a high voltage circuit using low power, the system comprising:
a sensor configured to optically couple a low voltage circuit to a high voltage circuit, the sensor capable of detecting a current that is representative of a high voltage in the high voltage circuit;
a switch configured to optically couple the low voltage circuit to the high voltage circuit, the switch, in response to being activated, causes the sensor to be energized; and
an output node coupled to the low voltage circuit, the output node generates an output voltage representative of the high voltage.

18. The system according to claim 17, wherein the sensor comprises a first light source and a first optical receiver that is electrically isolated from the first light source, and wherein the switch comprises a second light source and a second optical receiver that is electrically isolated from the second light source.

19. The system according to claim 18, further comprising a sampling resistor coupled to at least one of the second optical receiver and a bias resistor within the high voltage circuit to sample the high voltage.

20. The system according to claim 17, wherein the low voltage circuit comprises a gating voltage node that is coupled to the switch, the gating voltage activates the switch that causes the sensor to be energized.
